(19) United States
(12) Patent Application Publication
(10) Pub. No.: US 2012/0064844 A1
(43) Pub. Date: Mar. 15, 2012

(54) SEMICONDUCTOR INTEGRATED CIRCUIT AND RADIO COMMUNICATION DEVICE

(75) Inventors: Daisuke Miyashita, Kawasaki-shi (JP); Jun Deguchi, Kawasaki-shi (JP)

(73) Assignee: KABUSHIKI KAISHA TOSHIBA, Tokyo (JP)

(21) Appl. No.: 13/050,059

(22) Filed: Mar. 17, 2011

(30) Foreign Application Priority Data
Sep. 13, 2010 (JP) 2010-204717

(51) Int. Cl. H04B 1/40; H03H 11/16

(52) U.S. Cl. 455/84; 327/231

(57) ABSTRACT

According to one embodiment, a semiconductor integrated circuit includes a phase shifter, a plurality of phase matching detecting circuits, a output module. The phase shifter is configured to delay an input oscillation signal to generate a plurality of delay signals having phases different from each other. The plurality of phase matching detecting circuits is configured to store a second program for downloading a first program from an outside to the first area. The output module is configured to generate an output oscillation signal based on at least one of the delay signals having the phase difference determined to be within the predetermined range.

### CROSS REFERENCE TO RELATED APPLICATIONS

This application is based upon and claims the benefit of priority from the prior Japanese Patent Application No. 2010-204717, filed on Sep. 13, 2010, the entire contents of which are incorporated herein by reference.

### FIELD

Embodiments described herein relate generally to a semiconductor integrated circuit and a communication device.

### BACKGROUND

A radio communication device represented by a cellular phone can include a PLL (Phase Lock Loop) circuit for generating a local oscillator (hereinafter referred to as LO) signal. Since the LO signal is a reference signal to modulate and demodulate signals, phase noise included therein is required to be low. However, the LO signal generated by the PLL circuit may include phase noise. Further, it is difficult to generate an LO signal having low phase noise without increasing the scale of the PLL circuit and power consumption.

### BRIEF DESCRIPTION OF THE DRAWINGS

FIG. 1 is a schematic block diagram of a radio communication device 100 according to a first embodiment.

FIG. 2 is a schematic block diagram showing an example of the internal configuration of a phase adjustment circuit 200.

FIG. 3 is a diagram showing the principle of how phase noise is reduced by the phase adjustment circuit 200.

FIG. 4 is a schematic block diagram showing an example of a more specific internal configuration of the phase adjustment circuit 200.

FIG. 5 is a diagram showing the relationship between the delay element and the delay time of the delay signal.

FIG. 6 is a timing diagram showing an example of the operation performed by the phase adjustment circuit 200 of FIG. 4.

FIG. 7 is a circuit configuration showing an example of the phase matching detecting circuit 32k.

FIGS. 8A to 8C are timing diagrams showing an example of the operation performed by the phase matching detecting circuit 32k of FIG. 7.

FIG. 9 is a circuit block diagram showing another example of the phase matching detecting circuit 32k.

FIG. 10 is a circuit configuration showing an example of the internal configuration of the latch circuit 51.

FIGS. 11A to 11C are timing diagrams showing an example of the operation performed by the phase matching detecting circuit 32k′ of FIG. 9.

FIG. 12 is a modification example of the phase matching detecting circuit 32k′ of FIG. 9.

FIG. 13 is a schematic block diagram showing an example of an interpolation circuit 61 for interpolating the delay signal dly[k] and delay signal dly[l].

FIG. 14 is a timing diagram showing an example of the operation performed by the interpolation circuit 61 of FIG. 13.

FIG. 15 is a schematic block diagram showing an example of the internal configuration of a phase shifter 21′ using the interpolation circuit 61.

FIG. 16 is a schematic block diagram showing an example of the internal configuration of the phase shifter 21″.

FIG. 17 is a circuit configuration showing a specific example of the voltage dividing circuit 72.

FIG. 18 is a diagram showing that the phase of the reference signal REF matches those of a plurality of delay signals.

FIG. 19 is a schematic block diagram showing an example of the internal configuration of the MUX 23.

FIG. 20 is a schematic block diagram showing another example of the internal configuration of the MUX 23.

FIG. 21 is a schematic block diagram showing another example of the internal configuration of the MUX 23.

### DETAILED DESCRIPTION

In general, according to one embodiment, a semiconductor integrated circuit includes a phase shifter, a plurality of phase matching detecting circuits, an output module. The phase shifter is configured to delay an input oscillation signal to generate a plurality of delay signals having phases different from each other. The plurality of phase matching detecting circuits is configured to store a second program for downloading a first program from an outside to the first area. The output module is configured to generate an output oscillation signal based on at least one of the delay signals having the phase difference determined to be within the predetermined range.

Embodiments will now be explained with reference to the accompanying drawings.

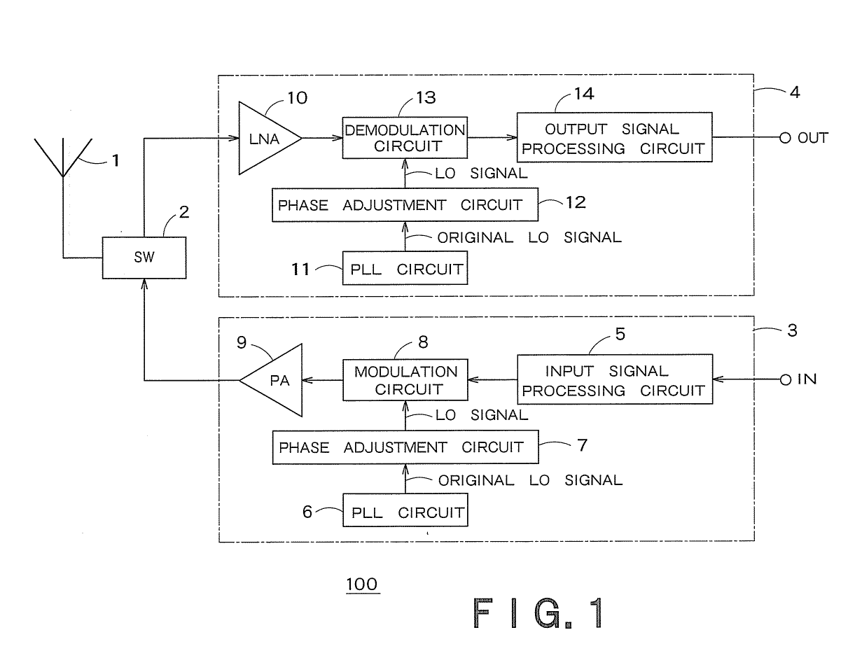

FIG. 1 is a schematic block diagram of a radio communication device 100 according to a first embodiment. The radio communication device 100 of FIG. 1 is mounted on a cellular phone, for example. The radio communication device 100 has an antenna 1 a switch (SW) 2, a signal transmitter 3 and a signal receiver 4. Note that the radio communication device 100 may include only one of the signal transmitter 3 and the signal receiver 4.

The antenna 1 transmits or receives a radio signal. The switch 2 controls whether the antenna 1 transmits or receives the radio signal. The signal transmitter 3 processes an input radio signal inputted from a baseband LSI (Large Scale Integrated circuit) etc. (not shown), and outputs the processed radio signal to the antenna 1. The signal receiver 4 processes the radio signal received by the antenna 1, and outputs the processed signal to the outside.

The signal transmitter 3 has an input signal processing circuit 5, a PLL circuit (second oscillation signal generating circuit) 6, a phase adjustment circuit 7, a modulation circuit 8 and a power amplifier (PA, transmitter) 9. The input signal processing circuit 5 processes a signal inputted from the outside. The PLL circuit generates an LO signal (hereinafter referred to as original LO signal.) This original LO signal may include phase noise. The phase adjustment circuit 7 generates an LO signal by reducing the phase noise of the original LO signal. Based on this LO signal, the modulation circuit 8 modulates the output signal from the input signal processing circuit 5. The power amplifier 9 amplifies the output signal from the modulation circuit 8, and outputs the amplified signal to the antenna 1.

The signal receiver 4 has an LNA (Low Noise Amplifier) 10, a PLL circuit (first oscillation signal generating circuit) 11, a phase adjustment circuit 12, a demodulation circuit 13 and an output signal processing circuit (output circuit) 14. The LNA 10 amplifies the radio signal received by the antenna 1. The PLL circuit generates an LO signal (hereinafter referred to as original LO signal.) This original LO signal may include phase noise. The phase adjustment circuit 12 generates an LO signal by reducing the phase noise of the original LO signal. Based on this LO signal, the demodulation circuit 13 demodulates the radio signal amplified by the LNA 10. The output signal processing circuit 14 processes the demodulated signal and outputs the processed signal to the outside.

As stated above, in the present embodiment, even when phase noise is included in the original LO signals generated by the PLL circuits 6 and 11, the phase adjustment circuits 7 and 12 reduce the phase noise, by which LO signals having low phase noise can be supplied to the modulation circuit 8 and the demodulation circuit 13. Accordingly, it is possible to transmit an input signal from the outside such as a sound/image signal by encoding the signal with a predetermined compression manner, or to stably reproduce the original sound/image signal without malfunction by decoding the signal received by the antenna 1. Hereinafter, the phase adjustment circuits 7 and 12 will be explained.

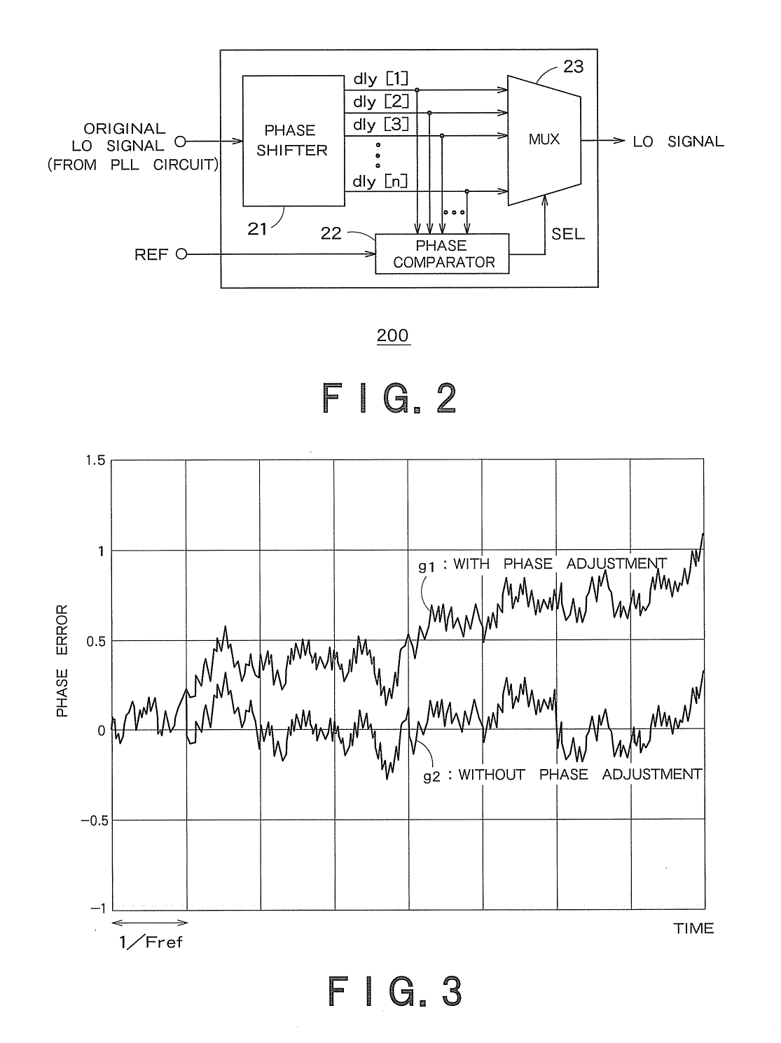

FIG. 2 is a schematic block diagram showing an example of the internal configuration of a phase adjustment circuit 200. The phase adjustment circuit 200 of FIG. 2 is mounted on a semiconductor integrated circuit, for example, and can be used as the phase adjustment circuit 7 or the phase adjustment circuit 12 of FIG. 1. The phase adjustment circuit 200 has a phase shifter 21, a phase comparator 22 and a MUX (output module) 23.

The original LO signal (input oscillation signal) generated by the PLL circuit is inputted to the phase shifter 21, for example. This original LO signal can include phase noise. The phase shifter 21 delays the original LO signal to generate “n” (“n” is a positive integer) delay signals dly[1] to dly[n] having the same frequency as the original LO signal and phases different from each other, and supplies the delay signals to the phase comparator 22 and the MUX 23. Frequency Flo of the original LO signal is 2.4 GHz, for example.

A reference signal REF generated by a crystal is inputted to the phase comparator 22, for example. Although the reference signal REF has a frequency Fref which is not so much high (13 MHz, for example), the reference signal REF includes little phase noise. A reference signal inputted into the PLL circuit in order to generate the original LO signal may be inputted into the phase comparator 22. The phase comparator 22 compares the reference signal REF with each of the delay signals dly[1] to dly[n] to detect a delay signal having a phase matching that of the reference signal REF. Further, the phase comparator 22 generates a control signal SEL indicative of the detected delay signal, and supplies the signal to the MUX 23.

In the present specification, “phases matching each other” means that “a phase difference is within a predetermined range” and does not necessarily mean that the phases strictly match each other, unless otherwise noted.

The delay signals dly[1] to dly[n] are inputted to the MUX 23 is inputted with. Based on the control signal SEL, the MUX 23 selects the delay signal detected by the phase comparator 22 among the delay signals dly[1] to dly[n], and outputs the selected signal as the LO signal (output oscillation signal.)

FIG. 3 is a diagram showing the principle of how phase noise is reduced by the phase adjustment circuit 200. In FIG. 3, the horizontal axis represents time based on a unit of 1/Fref, which is the cycle of the reference signal REF, and the vertical axis represents phase error of the LO signal (based on an arbitrary unit.)

When the original LO signal does not include phase noise, if the original LO signal and the reference signal REF synchronize with each other at a certain time, the original LO signal and the reference signal REF subsequently synchronize with each other. However, the original LO signal actually includes the phase noise. Therefore, as shown by curve g1 of FIG. 3, when phase adjustment is not performed, the phase noise is accumulated as time passes, and thus phase error is increased. In such a case, demodulation and modulation cannot be correctly performed by the modulation circuit 8 and the demodulation circuit 13 of FIG. 1.

On the other hand, in the present embodiment, as shown by curve g2, the phase comparator 22 in the phase adjustment circuit 200 detects a delay signal having a phase matching the phase of the reference signal REF in the cycle of the reference signal REF, and the MUX 23 outputs the detected delay signal as the LO signal. As stated above, since the LO signal is generated by adjusting the phase of the original LO signal, the phase error is not accumulated during one or more cycles of the reference signal REF, and thus the phase error can be reduced on average.

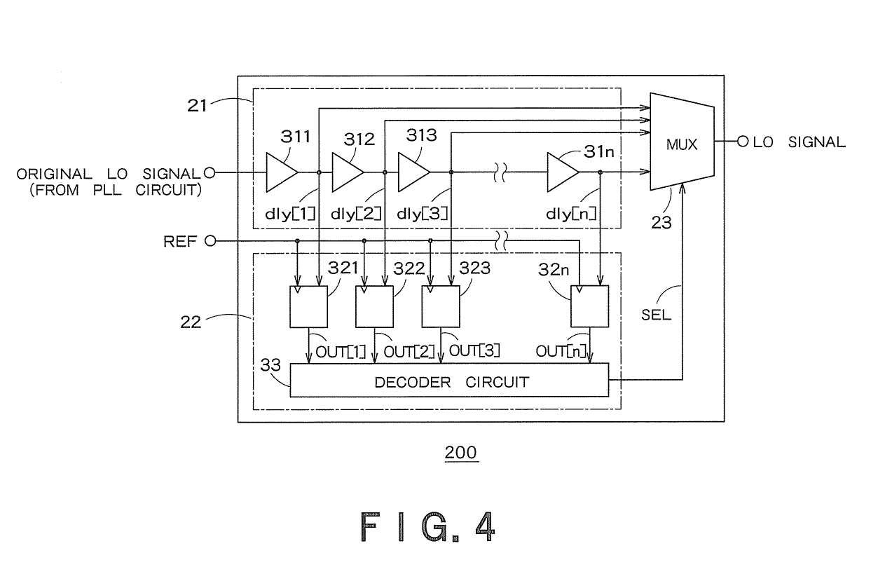

FIG. 4 is a schematic block diagram showing an example of a more specific internal configuration of the phase adjustment circuit 200.

The phase shifter 21 has “n” delay elements 311 to 31n connected in series. A delay element 31k (“k” is an integer of “1” to “n”) generates a delay signal dly[k] by delaying the original LO signal or a delay signal dly[k−1] by a unit delay time ΔT. The delay element is an inverter circuit, a NAND circuit, or a NOR circuit, for example. When a two-input logic circuit such as a NAND circuit is used as the delay element 31k, the input terminal to which the original LO signal or the delay signal dly[k−1] is not inputted can be used for various kinds of control. For example, when a NAND circuit is used, when one input is fixed to be low, the output is fixed to be high regardless of the level of the other input, which makes it possible not to transmit the signal to the delay elements arranged in the latter stages.

Accordingly, when the processes of the delay elements starting from a certain delay element are obviously unnecessary, power consumption can be reduced by not transmitting the signal to the unnecessary elements.

Here, it is desirable that many delay elements 31k are arranged so that delay signals having delay times different from each other are generated as many as possible. Accordingly, the difference in delay time between the delay signals becomes small, that is, phase resolution becomes small, by which a delay signal having a smaller phase difference from the reference signal REF can be selected to generate the LO signal. As a result, the accuracy of phase adjustment can be improved, and an LO signal having lower phase noise can be generated.

The phase comparator 22 has “n” phase matching detecting circuits 321 to 32n arranged corresponding to the delay signals dly[1] to dly[n], respectively and a decoder circuit 33. A phase matching detecting circuit 32k determines whether or not the phase of the reference signal REF matches that of the inputted delay signal dly[k]. The phase matching detecting circuit 32k outputs the determination result to the decoder circuit as OUT[k]. A specific example of the phase matching detecting circuit 32k will be explained in the second and third embodiments. The decoder circuit 33 controls the MUX 23 by generating the control signal SEL so that the MUX 23 selects and outputs a delay signal having a phase matching that of the reference signal REF.

Here, one of the characteristic features in the present embodiment is that the phase matching detecting circuit 32k determines whether or not the phase of the reference signal REF matches the phase of the inputted delay signal dly[k]. Because of this, the number of delay signals “n” can be increased.

As another example, it is possible to arrange flip-flops 321′ to 32n′ in the phase comparator 22 instead of the phase matching detecting circuits 321 to 32n in order to determine whether the phase of the inputted delay signal is advanced or delayed from the phase of the reference signal REF. In this case, the level of the phase difference between the original LO signal and each of the delay signals dly[1] to dly[n] must be increased in this order. This is because the decoder circuit 33 generates the control signal SEL by detecting the flip-flops 321′ to 32k′ each of which determines that “the phase of the delay signal is advanced” and the flip-flops 32(k+1)' to 32n each of which determines that “the phase of the delay signal is delayed.” As a result, the number of delay elements “n” is limited. More specifically, the phase difference between the delay signal dly[1] and the delay signal dly[n] must be 2π or less, and thus the number of delay elements “n” must satisfy the following equation (1).

2π*Flo*ΔT*n≦2π (1)

Therefore, the number of delay elements “n” cannot be made larger than 1/(Flo*ΔT). As a simple example, when the unit delay time ΔT is 3/10 of the cycle 1/Flo of the original LO signal, the number of delay elements “n” is equal to or less than “3”. As stated above, when the phase matching detecting circuits 32k are not used, the number of delay elements “n” is limited by the unit delay time ΔT of the delay element.

On the other hand, in the present embodiment, each of the phase matching detecting circuits 32k can determine whether or not the phase of the reference signal REF matches that of the delay signal. Therefore, it is unnecessary that the level of the phase difference between the original LO signal and each of the delay signals dly[1] to dly[n] increases in this order, and the number of delay elements “n” may be larger than 1/(Flo*ΔT).

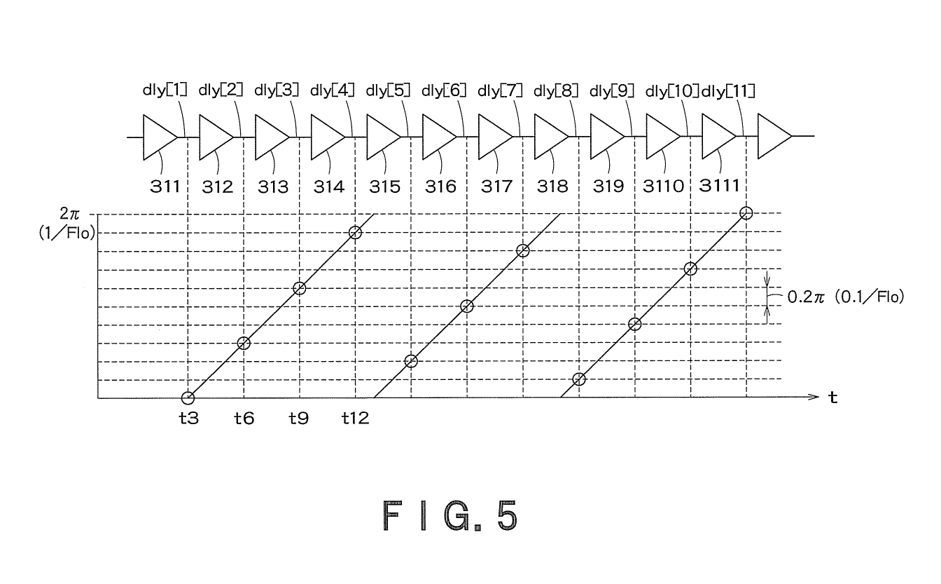

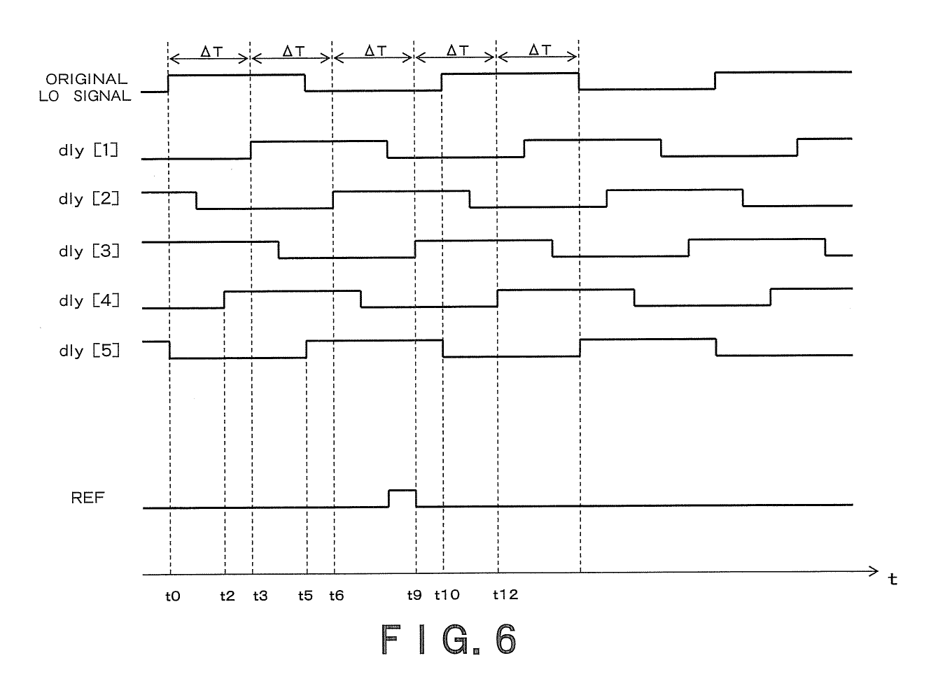

FIG. 5 is a diagram showing the relationship between the delay element and the delay time of the delay signal. In FIG. 5, the horizontal axis represents delay time, and the vertical axis represents the phase difference or the delay time of each delay signal using the delay signal dly[1] as a reference point. Further, FIG. 6 is a timing diagram showing an example of the operation performed by the phase adjustment circuit 200 of FIG. 4. FIG. 6 corresponds to FIG. 5. In the examples shown in FIGS. 5 and 6, the unit delay time ΔT is 3/10 of the cycle 1/Flo of the original LO signal.

As shown in FIGS. 5 and 6, the delay time of the delay signal increases by a unit of 3/10 cycle (phase difference is 2π* 3/10), and the delay time of the delay signal dly[n] with respect to the delay signal dly[1] may exceed cycle 1/Flo (phase difference is 2π). For example, the phase difference between the delay signal dly[5] and the delay signal dly[1] exceeds 2π. In the case of FIG. 5, by using “10” delay elements 311 to 3110, the delay signals dly[1] to dly[10] each having a delay time shifted by “0.1” cycle (phase difference is 2π* 1/10) can be generated. As stated above, the number of delay elements “n” can be increased up to “10” regardless of the unit delay time ΔT of the delay element, thereby improving the accuracy of phase adjustment.

In the example shown of FIG. 6, the phase matching detecting circuit detects, among the delay signals dly[1] to dly[10], a delay signal whose rising edge matches the falling edge of the reference signal REF. As shown in FIG. 6, because the delay signal dly[3] rises up and the reference signal REF falls down at time t9, the phase matching detecting circuit 323 determines that the reference signal REF matches the delay signal. On the other hand, each of the other phase matching detecting circuits 321, 322, and 324 to 3210 does not determine that the reference signal REF matches the inputted delay signal.

Based on the determination results OUT[1] to OUT[10] from the phase matching detecting circuits 321 to 3210, the decoder circuit 33 generates the control signal SEL so that the delay signal dly[3] is selected by the MUX 23 of FIG. 4.

In the example shown in FIG. 5 etc., the unit delay time ΔT is explained as 3/10 of the cycle 1/Flo of the original LO signal. However, when CMOS inverter circuits for 65 nm process are used, the actual unit delay time ΔT is 20 ps, for example, which is about 1/20 of the cycle 1/Flo of the original LO signal.

As stated above, in the first embodiment, a plurality of delay signals dly[1] to dly[n] are generated by delaying the original LO signal. Then, a delay signal having a phase matching that of the reference signal REF is selected among the delay signals dly[1] to dly[n], and the selected delay signal is set to be the LO signal. Since a delay signal having a phase matching that of the reference signal REF is selected by using the phase matching detecting circuits 321 to 32n, the number of delay elements “n” can be increased without being limited by the unit delay time ΔT of the delay elements 311 to 31n. As a result, it is possible to generate many delay signals having delay times different from each other and to select a delay signal having a phase matching that of the reference signal REF among the delay signals, thereby generating an LO signal including low phase noise.

### Second Embodiment

A second embodiment to be explained below is a specific example of the phase matching detecting circuit 32k.

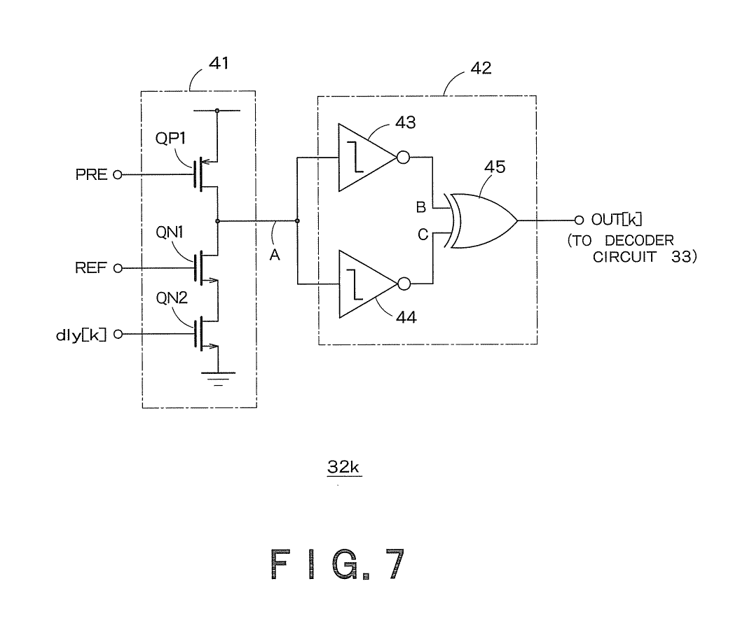

FIG. 7 is a circuit configuration showing an example of the phase matching detecting circuit 32k. The phase matching detecting circuit 32k of FIG. 7 refers to the falling edges of the reference signal REF and the rising edges of the delay signal dly[k] to determine whether or not the phase difference between the delay signal dly[k] and the reference signal REF is within the predetermined range, namely, whether or not the phase of the delay signal dly[k] matches that of the reference signal REF.

The phase matching detecting circuit 32k has a phase difference detecting circuit 41 and a determining circuit 42.

The phase difference detecting circuit 41 has a PMOS transistor QP1 and NMOS transistors QN1 and QN2 connected in series between a power source terminal and a ground terminal. A pre-charge signal PRE, the reference signal REF, and the delay signal dly[k] are inputted to the gates of the transistors QP1, QN1, and QN2, respectively. Further, a signal “A” is outputted from the connection node of the transistors QP1 and QN1. Note that, the delay signal dly[k] and the reference signal REF can be inputted to the gates of the transistors QN1 and QN2, respectively.

When the phase difference between the reference signal REF and the delay signal dly[k] is not within the predetermined range, the phase difference detecting circuit 41 sets the signal “A” to high (first reference voltage) or low (second reference voltage) depending on the phase difference. Here, high corresponds to a power supply voltage, and low corresponds to a ground voltage. On the other hand, when the phase difference is within the predetermined range, the phase difference detecting circuit 41 sets the signal “A” to a voltage Vm (first voltage), which is between high and low.

The determination circuit 42 has two comparators 43 and 44 and an XOR circuit (logic circuit) 45. The comparator 43 is an inverter circuit having a threshold value of voltage VthH (second voltage), which is higher than the voltage Vm and lower than the power supply voltage, and outputs a comparison result between the voltage of the signal “A” and the voltage VthH as a signal “B”. The comparator 44 is an inverter circuit having a threshold value of voltage VthL (third voltage), which is lower than the voltage Vm and higher than the ground voltage, and outputs a comparison result between the voltage of the signal “A” and the voltage VthL as a signal “C”. The XOR circuit 45 outputs an exclusive OR between the signal “B” and the signal “C” as a determination result OUT[k].

When the signal “A” is high or low, the determination circuit 42 determines that the phase difference between the reference signal REF and the delay signal dly[k] is not within the predetermined range, and sets the determination result OUT[k] to be low. On the other hand, when the signal “A” is the voltage Vm, the determination circuit 42 determines that the phase difference between the reference signal REF and the delay signal dly[k] is within the predetermined range, and sets the determination result OUT[k] to be high.

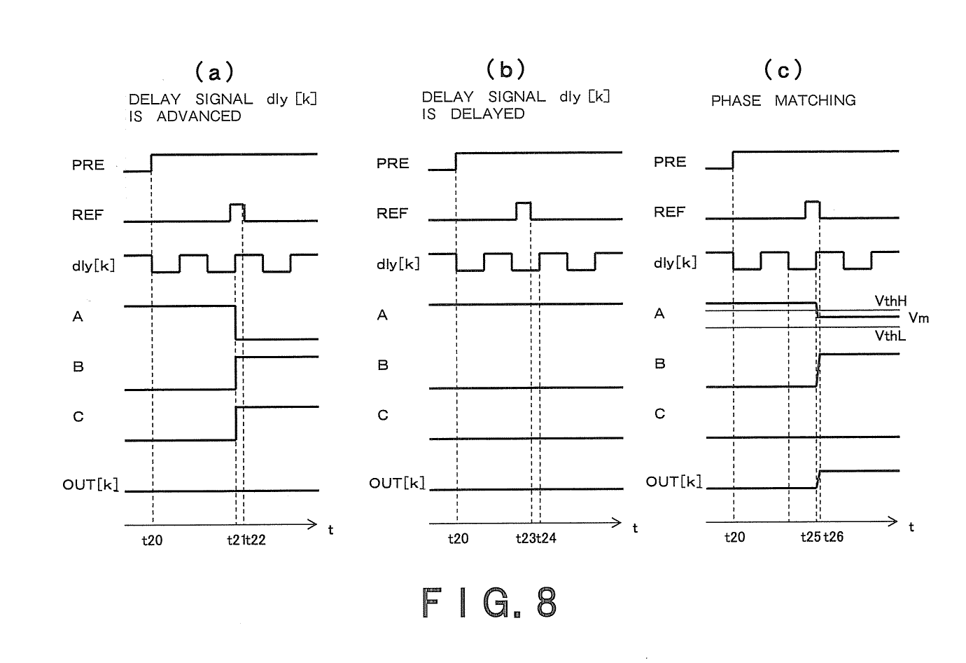

FIGS. 8A to 8C are timing diagrams showing an example of the operation performed by the phase matching detecting circuit 32k of FIG. 7. The operation of the phase matching detecting circuit 32k of FIG. 7 will be explained in more detail with reference to FIGS. 8A to 8C.

Firstly, a timing control circuit (not shown) sets the pre-recharge signal PRE to be low. Because of this, the transistor QP1 turns on to be conducted, and the signal “A” is set to be high. Next, at time t20, the pre-charge signal PRE is set to be high, and the transistor QP1 turns off. Hereinafter, explanation will be made according to the situation.

FIG. 8A is a timing diagram where the phase difference between the reference signal REF and the delay signal dly[k] exceeds the predetermined range and the phase of the delay signal dly[k] is advanced from the phase of the reference signal REF. At time t21, the delay signal dly[k] rises up, and after that, at time t22, the reference signal REF falls down. During time t21 to t22, because both of the reference signal REF and the delay signal dly[k] are high, and thus both of the transistors QN1 and QN2 turn on to be conducted, and the signal “A” is set to be low. As a result, the signals “B” and “C” outputted from the comparators 43 and 44 respectively are both high, and the XOR circuit 45 sets the determination result OUT[k] to be low. As stated above, the phase matching detecting circuit 32k can detect that the phase difference between the reference signal REF and the delay signal dly[k] is not within the predetermined range.

FIG. 8B is a timing diagram where the phase difference between the reference signal REF and the delay signal dly[k] exceeds the predetermined range and the phase of the delay signal dly[k] is delayed from the phase of the reference signal REF. At time t23, the reference signal REF falls down, and after that, at time t24, the delay signal dly[k] rises up. Because there is no period when both of the reference signal REF and the delay signal dly[k] are high, the signal “A” stays in high. As a result, both of the signals “B” and “C” outputted from the comparators 43 and 44 are low, and the XOR circuit 45 sets the determination result OUT[k] to be low. As stated above, the phase matching detecting circuit 32k can detect that the phase difference between the reference signal REF and the delay signal dly[k] is not within the predetermined range.

FIG. 8C is a timing diagram where the phase difference between the reference signal REF and the delay signal dly[k] is within the predetermined range. At time t25, the delay signal dly[k] rises up, and immediately after that, at time t26, the reference signal REF falls down. At time t25, both of the transistors QN1 and QN2 turn on, and the voltage of the signal “A” starts to fall. However, immediately after that, at time t26, the transistor QN1 turns off. Therefore, the signal “A” does not fall to low, and is set to be the voltage Vm between high and low. Because the threshold value VthH of the comparator 43 is higher than the voltage Vm, the signal “B” is set to be high. On the other hand, because the threshold value VthL of the comparator 44 is lower than the voltage Vm, the signal “C” is set to be low. As a result, the XOR circuit 45 sets the determination result OUT[k] to be high. In such a manner, when the period from the rising of the delay signal dly[k] to the falling of the reference signal REF is within a predetermined time, the phase matching detecting circuit 32k can detect that the phase difference between the delay signal dly[k] and the reference signal REF is within the predetermined range.

In the phase matching detecting circuit 32k of FIG. 7, when the voltage of the signal “A” is set between the voltage VthL and the voltage VthH, the determination result OUT[k] is set to be high. This operation requires that the delay signal dly[k] rises up during a period where the reference signal REF is high so that the voltage of the signal “A” becomes lower than the voltage VthH, and further requires that the reference signal REF falls down before the voltage of the signal “A” becomes lower than the voltage VthL. When the phase difference between the reference signal REF and the delay signal dly[k] is within a range satisfying these conditions, it is determined that the phase of the reference signal REF matches that of the delay signal dly[k].

Note that, when the rising edge of the reference signal REF matches the falling edge of the delay signal dly[k], the determination result OUT[k] is also set to be high. However, in this case, the phase of the reference signal REF does not match that of the delay signal dly[k], and thus this is an unnecessary operation. Thus, the decoder circuit 33 performs mask processing in order to invalidate this determination result. The mask processing can be performed by using the signals “B” and “C” of another phase matching detecting circuit.

For example, when the determination result OUT[k] of the phase matching detecting circuit 32k to which the delay signal dly[k] is inputted is high, the decoder circuit 33 confirms: the signal “B” (hereinafter referred to as signal B[k−1]) of the phase matching detecting circuit 32(k−1) to which the delay signal dly[k−1] is inputted in the preceding stage; and the signal “B” (hereinafter referred to as signal B[k+1]) of the phase matching detecting circuit 32(k+1) to which the delay signal dly[k+1] is inputted in the following stage. As shown in FIG. 8C, when the falling edge of the reference signal REF matches the rising edge of the delay signal dly[k], the phase of the delay signal dly[k−1] is advanced from the phase of the reference signal REF (in the state of FIG. 8A), and thus the signal B[k−1] is high. On the other hand, the phase of the delay signal dly[k+1] is delayed from the phase of the reference signal REF (in the state of FIG. 8B), and the signal B[k+1] is low. To the contrary, when the signal B[k−1] is low and the signal B[k+1] is high, the decoder circuit 33 performs the mask processing since it is possible to determine that the rising edge of the reference signal REF matches the falling edge of the delay signal dly[k].

As stated above, in the second embodiment, phase matching is detected by using a simplified phase matching detecting circuit 32k having about ten transistors as shown in FIG. 7, by which an LO signal including low phase noise can be generated.

### Third Embodiment

In the phase matching detecting circuit 32k of the second embodiment, one signal “A” is set to the voltage Vm which is between high and low. In a third embodiment to be explained below, two signals are set to a voltage which is between high and low.

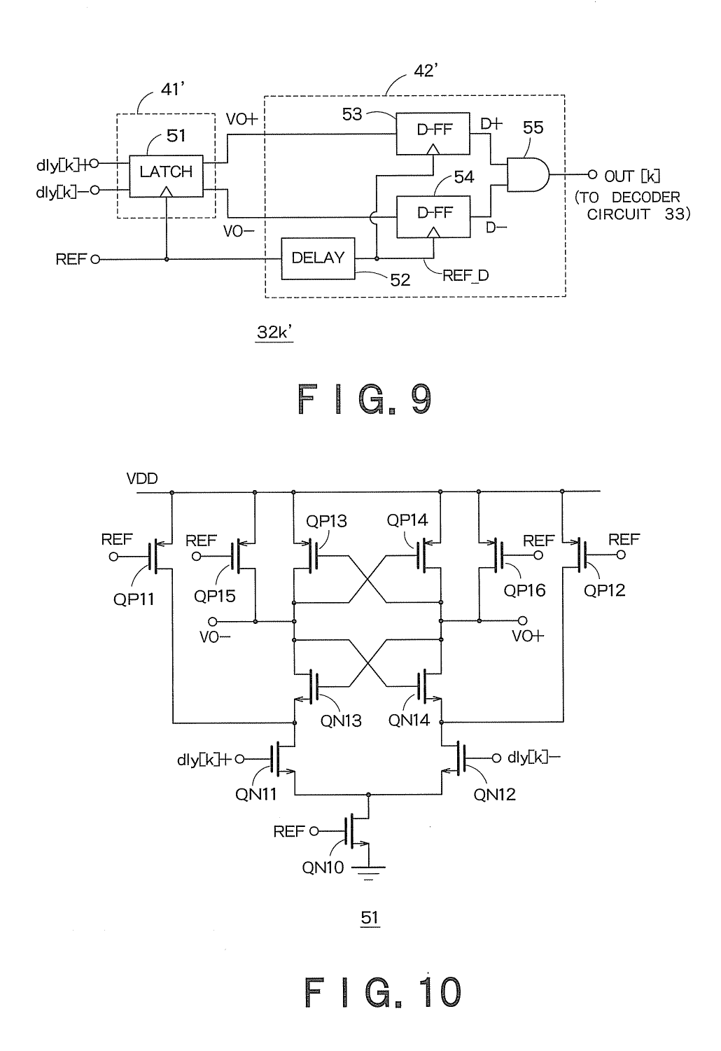

FIG. 9 is a circuit block diagram showing another example of the phase matching detecting circuit 32k. In FIG. 9, the same components as those in FIG. 7 are given the similar reference numerals, and differences will be mainly explained hereinafter.

A phase matching detecting circuit 32k′ of FIG. 9 refers to the rising edges of the reference signal REF and the delay signal dly[k] to determine whether or not the phase difference between the delay signal dly[k] and the reference signal REF is within the predetermined range, namely, whether or not the phase of the delay signal dly[k] matches that of the reference signal REF.

A phase difference detecting circuit 41′ has a latch circuit 51 to which a delay signal dly[k]+ and an inversion signal dly[k]− generated by an inverting circuit (not shown) from the delay signal dly[k] are inputted. The reference signal REF is inputted to the latch circuit 51 as a clock signal, and the levels of the delay signal dly[k]+ and the inversion signal dly[k]− are compared in synchronization with the rising edges of the reference signal REF.

FIG. 10 is a circuit configuration showing an example of the internal configuration of the latch circuit 51. A PMOS transistor QP11 and an NMOS transistor QN11 are connected in series between a power source terminal VDD and an NMOS transistor QN10, and a PMOS transistor QP12 and an NMOS transistor QN12 are connected in series between the power source terminal VDD and the NMOS transistor QN10. A PMOS transistor QP13 and an NMOS transistor QN13 are connected in series between the power source terminal VDD and the transistor QN10, and a PMOS transistor QP14 and an NMOS transistor QN14 are connected in series between the power source terminal VDD and the transistor QN10. A PMOS transistor QP15 is connected in parallel with the transistor QP13, and the PMOS transistor QP16 is connected in parallel with the transistor QP14.

The reference signal REF is inputted to the gate of each of the transistors QP11, QP12, QP15, QP16, and QN10. The delay signal dly[k]+ and the inversion signal dly[k]− are inputted to the gates of the transistors QN11 and QN12, respectively. The connection node of the transistors QP13 and QN13 is connected to the gates of the transistors QP14 and QN14, and outputs a signal VO−. The connection node of the transistors QP14 and QN14 is connected to the gates of the transistors QP13 and QN13, and outputs a signal VO+.

When the phase difference between the reference signal REF and the delay signal dly[k] is not within the predetermined range, the latch circuit 51 shown in FIGS. 9 and 10 sets one of the signals VO+ and VO− to be low and sets the other to be high depending on the phase difference. On the other hand, when the phase difference is within the predetermined range, the phase difference detecting circuit 41′ sets the signals VO+ and VO− to the voltage Vm which is between high and low.

On the other hand, a determination circuit 42′ of FIG. 9 has a delay circuit 52 (DELAY) 52, D flip-flops (D-FF) 53 and 54 and an AND circuit (logic circuit) 55. The delay circuit 52 generates a delayed reference signal REF_D by delaying the reference signal REF. The delayed reference signal REF_D is inputted to the D flip-flops 53 and 54 as a clock signal. The D flip-flops 53 and 54 hold the values of the signals VO+ and VO− in synchronization with the rising edges of the delayed reference signal REF_D, and output the values as signals D+ and D−, respectively. The AND circuit 55 outputs the logical product of the signal D+ and the signal D− as the determination result OUT[k].

When one of the signals VO+ and VO− is low, the determination circuit 42′ determines that the phase difference between the reference signal REF and the delay signal dly[k] is not within the predetermined range, and sets the determination result OUT[k] to be low. On the other hand, when the signals VO+ and VO− are the voltage Vm, the determination circuit 42 determines that the phase difference between the reference signal REF and the delay signal dly[k] is within the predetermined range, and sets the determination result OUT[k] to be high.

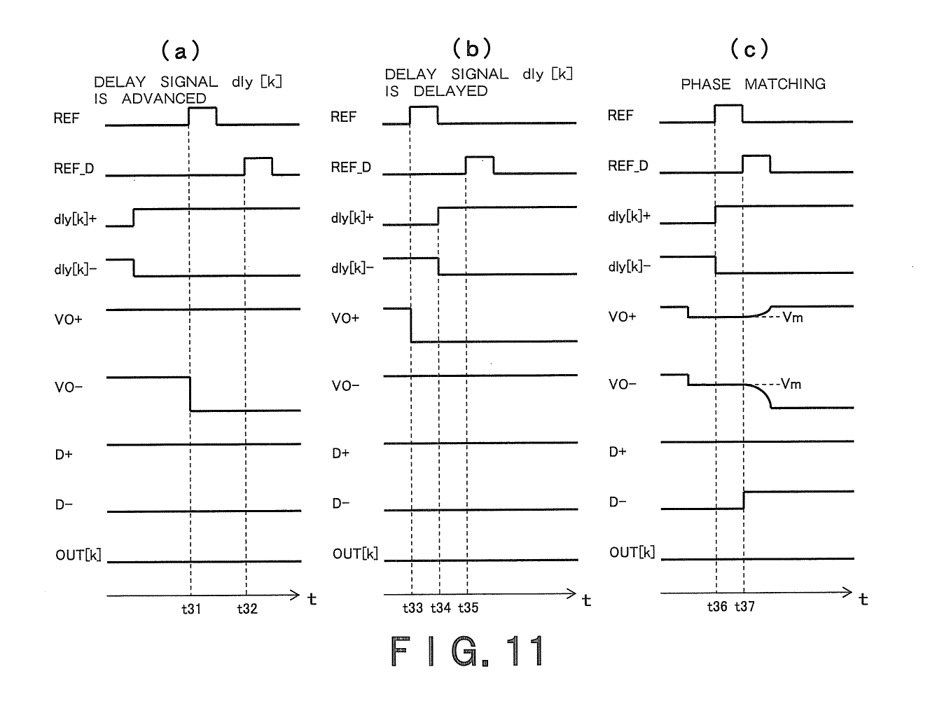

FIGS. 11A to 11C are timing diagrams showing an example of the operation performed by the phase matching detecting circuit 32k′ of FIG. 9. The operation of the phase matching detecting circuit 32k′ of FIG. 9 will be explained in more detail with reference to FIGS. 11A to 11C.

While the reference signal REF is low, the transistors QP11, QP12, QP15, and QP16 turn on, and the signals VO+ and VO−, the connection node of the transistors QN11 and QN13, and the connection node of the transistors QN12 and QN14 are set to be high. Hereinafter, explanation will be made according to the situation.

FIG. 11A is a timing diagram where the phase difference between the reference signal REF and the delay signal dly[k] exceeds the predetermined range, and the phase of the delay signal dly[k] is advanced from the phase of the reference signal REF. When the reference signal REF rises up at time t31, the delay signal dly[k]+ is high and the inversion signal dly−[k] is low. Therefore, at time t31, the transistors QN10, QN11, QN13, and QN14 of FIG. 10 turn on. Since the transistors QN10, QN11, and QN13 turn on, the voltage of the signal VO− decreases and finally reaches low. On the other hand, since the transistor QN12 is off, the signal VO+ stays in high.

After that, when the delayed reference signal REF_D rises up at time t32, the D flip-flops 53 and 54 of FIG. 9 hold the values of the signals VO+ and VO− and set the signal D+ to be high and the signal D− to be low, respectively. Then, the AND circuit 55 sets the determination result OUT[k] to be low, in such a manner, the phase matching detecting circuit 32k′ can detect that the phase difference between the reference signal REF and the delay signal dly[k] is not within the predetermined range.

FIG. 11B is a timing diagram where the phase difference between the reference signal REF and the delay signal dly[k] exceeds the predetermined range and the phase of the delay signal dly[k] is delayed from the phase of the reference signal REF. In this case, when the reference signal REF rises up at time t33, the delay signal dly[k]+ is low and the inversion signal dly−[k] is high. Therefore, the polarities of the signals VO+ and VO− are reversed to those of FIG. 11A, but the determination result OUT[k] is set to be low by performing a similar operation.

FIG. 11C is a timing diagram where the phase difference between the reference signal REF and the delay signal dly[k] is within the predetermined range. At time t36, the reference signal REF rises up, and at the same time, the delay signal dly[k]+ changes from low to high and the inversion signal dly−[k] changes from high to low. At time t36, the delay signal dly[k]+ is in transition from low to high and the inversion signal dly[k]− is in transition from high to low, and thus the difference therebetween is small. Therefore, the signals VO+ and VO− outputted from the latch circuit 51 of FIG. 9 are in a metastable state. As a result, the voltage Vm which is higher than the intermediate voltage between high and low is outputted for a certain time.

Further, while the signals VO+ and VO− output the voltage Vm, when the delayed reference signal REF_D rises up at time t37, the D flip-flops 53 and 54 set the signals D+ and D− to be high since the voltage Vm is higher than the intermediate voltage between high and low. Accordingly, the AND circuit 55 sets the determination result OUT[k] to be high. In such a manner, the phase matching detecting circuit 32k′ can detect that the phase difference between the delay signal dly[k] and the reference signal REF is within the predetermined range.

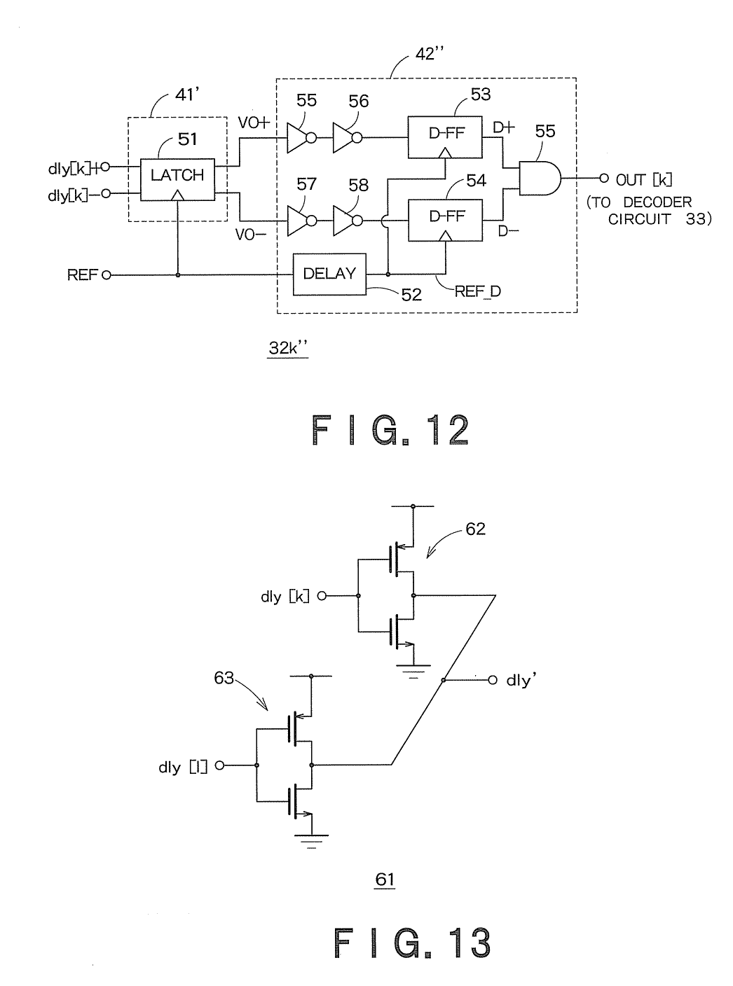

FIG. 12 is a modification example of the phase matching detecting circuit 32k′ of FIG. 9. A determination circuit 42″ of FIG. 12 has inverter circuits 55 and 56 between the signal VO+ and the D flip-flop 53, and inverter circuits 57 and 58 between the signal VO− and the D flip-flop 54. Two inverter circuits 55 and 56 amplify the voltage Vm of the signal VO+ in FIG. 11C to high, and two inverter circuits 57 and 58 also amplify the voltage Vm of the signal VO− to high. Accordingly, the signals D+ and D− can be surely set to be high by the D-FFs 53 and 54.

As stated above, in the third embodiment, phase matching is detected by using the phase matching detecting circuit 32k′ or 32k″ similar to the second embodiment, by which an LO signal including low phase noise can be generated.

### Fourth Embodiment

In the above embodiments, the phase shifter 21 includes the delay elements connected in series to generate the delay signals dly[1] to dly[n] each of which is shifted by the unit delay time ΔT of the delay element. On the other hand, in a fourth embodiment to be explained below, the number of delay signals are further increased by interpolating the delay signals dly[1] to dly[n].

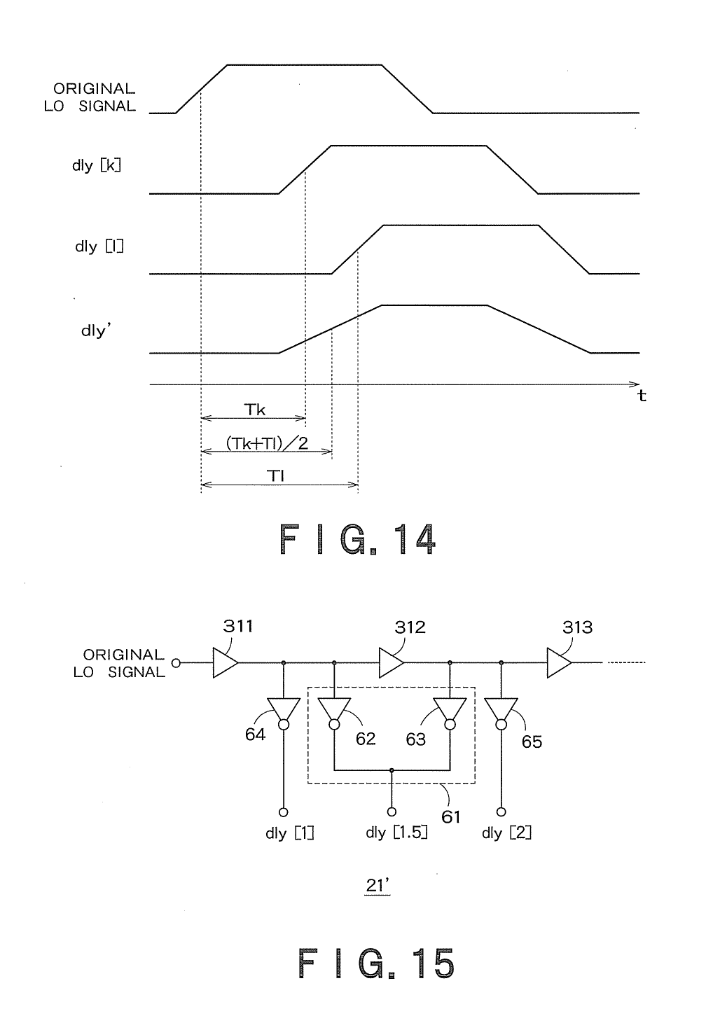

FIG. 13 is a schematic block diagram showing an example of an interpolation circuit 61 for interpolating the delay signal dly[k] and delay signal dly[l] (“l” is an integer of “1” to “n”). Further, FIG. 14 is a timing diagram showing an example of the operation performed by the interpolation circuit 61 of FIG. 13.

Arbitrary two delay signals dly[k] and dly[l] among the delay signals dly[1] to dly[n] of FIG. 4 are inputted into the interpolation circuit 61. The interpolation circuit 61 has an inverter circuit 62 to which the delay signal dly[k] is inputted, and an inverter circuit 63 to which the delay signal dly[l] is inputted. These output terminals are short-circuited to generate a delay signal dly′. The characteristics of these two inverter circuits are substantially the same.

Accordingly, as shown in FIG. 14, by interpolating the delay signal dly[k] having a delay time Tk to the original LO signal and the delay signal dly[l] having a delay time Tl, a signal dly′ having a delay time (Tk+Tl)/2 is newly generated. This signal dly′ can be used as one of the delay signals.

FIG. 15 is a schematic block diagram showing an example of the internal configuration of a phase shifter 21′ using the interpolation circuit 61. The phase shifter 21′ of FIG. 15 has inverter circuits 62 to 65 in addition to the delay elements 311 to 313. In practice, more delay elements and inverter circuits are further connected, but those are omitted in FIG. 15.

When ignoring the delay time of the inverter circuit itself, the inverter circuit 64 connected to the output terminal of the first delay element 311 generates the delay signal dly[1] having a delay time ΔT. Further, the inverter circuit 65 connected to the output terminal of the second delay element 312 generates the delay signal dly[2] having a delay time 2ΔT. Further, the interpolation circuit 61 is formed of the inverter circuit 62 connected to the output terminal of the delay element 311, and the inverter circuit 63 connected to the output terminal of the delay element 312. The interpolation circuit 61 generates a delay signal dly[1.5] having a delay time 1.5ΔT.

Similar to this, the phase shifter 21′ of FIG. 15 can generate delay signals each of which is shifted by a delay time 0.5ΔT. It is certainly possible to further interpolate these delay signals to generate delay signals each of which is shifted by a delay time shorter than 0.5ΔT. Note that, the inverter circuits 64 and 65 etc. are arranged in order to uniform the polarity of each delay signal, but the polarity differences may be considered by the phase matching detecting circuits 32k without arranging the inverter circuits.

As stated above, in the fourth embodiment, the outputs of two inverter circuits are short-circuited to generate a delay signal by interpolating the outputs of the delay elements. Therefore, it is possible to generate delay signals each of which is shifted by a delay time shorter than the unit delay time ΔT of the delay element, thereby improving the accuracy of phase adjustment.

### Fifth Embodiment

As stated above, each of the phase shifters 21 and 21′ in the first to third embodiments includes a plurality of delay elements connected in series to generate the delay signals. On the other hand, in a fifth embodiment to be explained below, a plurality of frequency-divided signals are generated by dividing the original LO signal, and the voltage of these frequency-divided signals is divided by using resistance elements to generate delay signals.

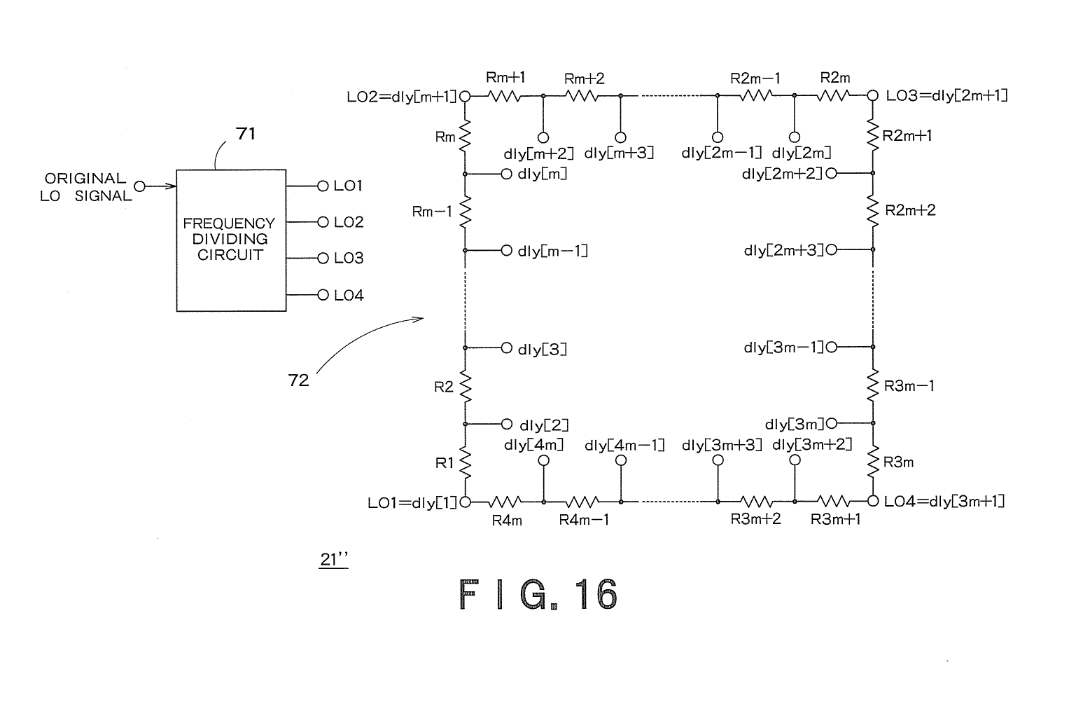

FIG. 16 is a schematic block diagram showing an example of the internal configuration of the phase shifter 21″. The phase shifter 21″ has a frequency dividing circuit 71 and the voltage dividing circuit 72.

The frequency dividing circuit 71 divides the frequency of the original LO signal to generate “4” phase frequency-divided signals LO1 to LO4 having phases different from each other by “90” degrees, for example. The frequency dividing circuit 71 can be implemented by a quadrature VCO, a ring oscillator, or a polyphase filter, for example. Note that, the frequency dividing circuit 71 may generate not only “4” phase frequency-divided signals but also “8” or “16” phase frequency-divided signals.

The voltage dividing circuit 72 has 4m resistances R1 to R4m. The voltage dividing circuit 72 further divides the “4” phase frequency-divided signals LO1 to LO4 into “m” by the resistances R1 to R4m to generate 4*m(=“n”) phase delay signals dly[1] to dly[n].

The resistances R1 to Rm are connected in series between the frequency-divided signal LO1 and the frequency-divided signal LO2. The resistances Rm+1 to R2m are connected in series between the frequency-divided signal LO2 and the frequency-divided signal LO3. The resistances R2m+1 to R3m are connected in series between the frequency-divided signal LO3 and the frequency-divided signal LO4. The resistances R3m+1 to R4m are connected in series between the frequency-divided signal LO4 and the frequency-divided signal LO1. Here, it is preferable that the a resistance value becomes larger as the resistance is connected closer to the frequency-divided signal so that the delay times of the delay signals dly[1] to dly[4m] are set at regular intervals. For example, R1>R2> . . . <Rm−1<Rm.

The delay signal dly[k+1] is outputted from the connection node of the resistance Rk (k=“1” to 4m−1) and the resistance Rk+1, and the delay signal dly[1] is outputted from the connection node of the resistance R4m and the resistance R1. For example, the delay signal dly[2] is obtained by dividing the voltage of the frequency-divided signals LO1 and LO2 by the resistances R1 to Rm. The delay time of the delay signal dly[2] obtained by the voltage division has a value between the delay time of the frequency-divided signal LO1 and the delay time of the frequency-divided signal LO2. The other delay signals are similarly arranged.

Note that, each of the following pairs shows the same signal: the frequency-divided signal LO1 and the delay signal dly[1]; LO2 and dly[m+1]; LO3 and dly[2m+1]; and LO4 and dly[3m+1].

By appropriately setting the resistance values of the resistances R1 to R4m, the delay times of the delay signals dly[1] to dly[4m] can be set at regular intervals.

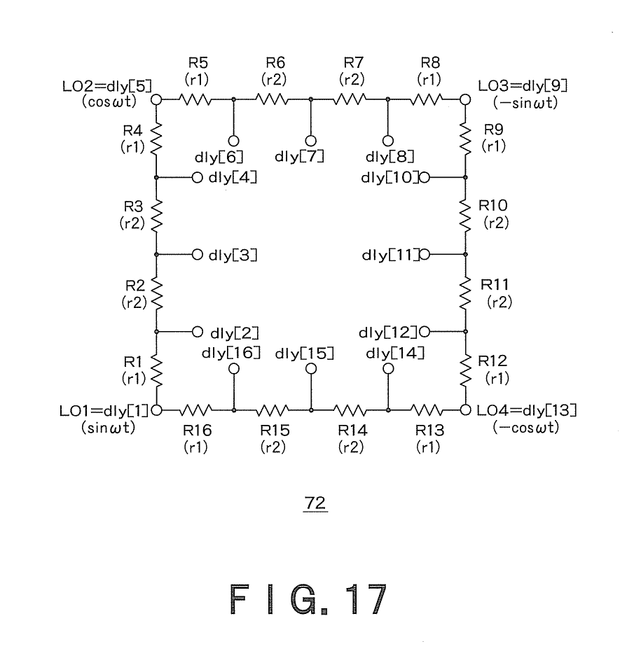

FIG. 17 is a circuit configuration showing a specific example of the voltage dividing circuit 72. The voltage dividing circuit 72 of FIG. 17 is an example where “m”=4 in the voltage dividing circuit 72 of FIG. 16. Hereinafter, conditions required for the voltage dividing circuit 72 of FIG. 17 will be obtain in order to set the delay times of the delay signals dly[1] to dly[16] at regular intervals.

The resistance values of the resistances R1 to R16 must be symmetrically set between two arbitrary frequency-divided signals. Therefore, the resistance value of eight resistances closest to the frequency-divided signals are defined as r1, and the resistance value of the other resistances are defined as r2. Further, because the LO signal and the frequency-divided signals LO1 to LO4 generated therefrom have a high frequency of about 2.4 GHz, the waveform can be approximated not by a rectangle but by a sine wave. Additionally, considering that the frequency-divided signals LO1 to LO4 have phases different from each other by “90” degrees, the following equations (2) to (5) can be established.

LO1=sin ωt (2)

LO2=cos ωt (3)

LO3=−sin ωt (4)

LO4=−cos ωt (5)

Here, ω=2π*Flo. For example, the delay signals dly[2] to dly[4] have a voltage obtained by dividing the voltage of the frequency-divided signals LO1 and LO2 by the resistances R1 to R4. Accordingly, dly[1] to dly[5] can be expressed by the following equations (6) to (10).

$$\begin{matrix}dly [ 1 ] = sin ω t & ( 6 ) \\ dly [ 2 ] = \frac{r 1 + 2 r 2}{2 r 1 + 2 r 2} sin ω t + \frac{r 1}{2 r 1 + 2 r 2} cos ω t = A sin ( ω t + α ) & ( 7 ) \\ dly [ 3 ] = \frac{1}{2} sin ω t + \frac{1}{2} cos ω t = \frac{1}{\sqrt{2}} sin ( ω t + 45 ) & ( 8 ) \\ dly [ 4 ] = \frac{r 1}{2 r 1 + 2 r 2} sin ω t + \frac{r 1 + 2 r 2}{2 r 1 + 2 r 2} cos ω t = A sin ( ω t + β ) & ( 9 ) \\ dly [ 5 ] = cos ω t = sin ( ω t + 90 ) & ( 10 )\end{matrix}$$

Here, A, α, and β can be expressed by the following equations (11) to (13).

$$\begin{matrix}A = \sqrt{{( \frac{r 1 + 2 r 2}{2 r 1 + 2 r2} )}^{2} + {( \frac{r 1}{2 r 1 + 2 r 2} )}^{2}} & ( 11 ) \\ α = arctan \frac{r 1}{2 r 1 + 2 r 2} & ( 12 ) \\ β = arctan \frac{r 1 + 2 r 2}{r 1} & ( 13 )\end{matrix}$$

Then, the resistance values r1 and r2 are set to satisfy the following equation (14).

r1=√2*r2 (14)

Accordingly, α=22.5 degrees and β=67.5 degrees, by which the delay signals dly[1] to dly[5] can have phases shifted from each other by 22.5 degrees. As a result, the delay signals dly[1] to dly[16] have phases different from each other by 360/16 degrees, and the delay times are set at regular intervals.

As stated above, the phase shifter 21″ in the fourth embodiment firstly generates a plurality of frequency-divided signals LO1 to LO4 by dividing the LO signal by the frequency dividing circuit 71. Next, the voltages of the frequency-divided signals LO1 to LO4 are divided by a plurality of resistances to generate the delay signals dly[1] to dly[4m] of the LO signal. Since a delay element such as a CMOS inverter circuit is not used, influence of manufacturing variation can be restrained.

In FIGS. 16 and 17, the resistances may be replaced by general impedance elements such as capacitors, inductors, and transistors the gate of which is biased to a predetermined potential. Further, the interpolation circuit 61 of FIG. 13 can interpolate two of the delay signals generated in FIGS. 16 and 17 to generate a delay signal having a delay time shifted by a shorter time.

### Sixth Embodiment

A sixth embodiment to be explained below relates to the decoder circuit 33 and the MUX 23 of FIG. 4.

The decoder circuit 33 of FIG. 4 generates the control signal SEL indicative of a delay signal having a phase matching that of the reference signal REF based on the determination results OUT[1] to OUT[n] from the phase matching detecting circuits 321 to 32n. The control signal SEL is a digital signal having “n” bits. In the present embodiment, the decoder circuit 33 sets only one bit of the control signal SEL to be high as stated below.

When the phase matching detecting circuits 321 to 32n of FIG. 4 determine that the phase of the delay signal dly[k], which is one of the delay signals dly[1] to dly[n], matches the phase of the reference signal REF, k-th bit of the control signal SEL is set to be high and the other bits are set to be low.

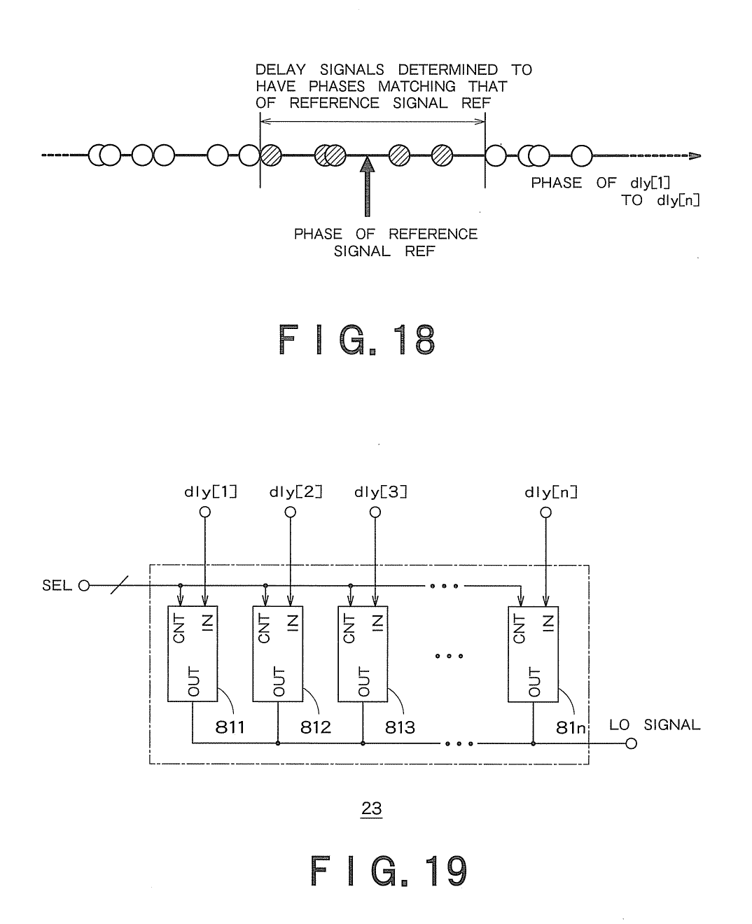

As explained in the first embodiment, when the number of delay elements “n” is large, a plurality of phase matching detecting circuits 32k may determine that the phase of the delay signal dly[k] matches the phase of the reference signal REF. FIG. 18 is a diagram showing that the phase of the reference signal REF matches those of a plurality of delay signals. In FIG. 18, the phase of the reference signal REF matches those of five delay signals. In this case, the decoder circuit 33 sets only one bit of the control signal SEL to be high in accordance with a predetermined priority. For example, the phase matching detecting circuit which detects the phase matching firstly has the highest priority in the order of the phase matching detecting circuits 321 to 32n. Because of this, the operation of the phase matching detecting circuits following that firstly detecting the phase matching can be stopped, thereby reducing power consumption.

On the other hand, when none of the phase matching detecting circuits 32k determines that the phase of the reference signal REF matches that of the delay signal, the decoder circuit 33 sets a predetermined one bit of the control signal SEL to high. Instead, it is also possible to hold the one bit which is set to be high in the preceding cycle so that phase variation between the current cycle and the preceding cycle becomes small.

FIG. 19 is a schematic block diagram showing an example of the internal configuration of the MUX 23. The MUX 23 has “n” output buffers (output circuits) 811 to 81n arranged corresponding to the delay signals dly[1] to dly[n], respectively. The corresponding delay signal dly[k] is inputted to an input terminal IN of the output buffer 81k. Further, the k-th bit of the control signal SEL is inputted to a control terminal CNT of the output buffer 81k. Furthermore, output terminals OUT of the output buffers 811 to 81n are short-circuited to output the LO signal.

Each of the output buffers 811 to 81n in the present embodiment is tri-state buffer capable of outputting high-impedance (hereinafter referred to as Hi-Z). That is, the output buffer 81k outputs, from the output terminal OUT, the delay signal dly[k] inputted into the input terminal IN when high is inputted into the control terminal CNT, and sets the output terminal OUT to be Hi-Z when low is inputted into the control terminal CNT.

Since the decoder circuit 33 sets one bit of the control signal SEL to be high, from one of the output buffers, the delay signal corresponding thereto is outputted, thereby generating the LO signal.

As stated above, in the sixth embodiment, the output buffers 811 to 81n capable of outputting Hi-Z are arranged corresponding to the delay signals dly[1] to dly[n] respectively. Further, the decoder circuit 33 generates the control signal SEL in which only one bit is set to high, and inputs it into each of the output buffers 811 to 81n. Therefore, the MUX 23 can surely generate the LO signal by selecting one of the delay signals dly[1] to dly[n].

### Seventh Embodiment

In the sixth embodiment, the output terminals of all output buffers are short-circuited. On the other hand, in a seventh embodiment to be explained below, the output buffers are connected in series.

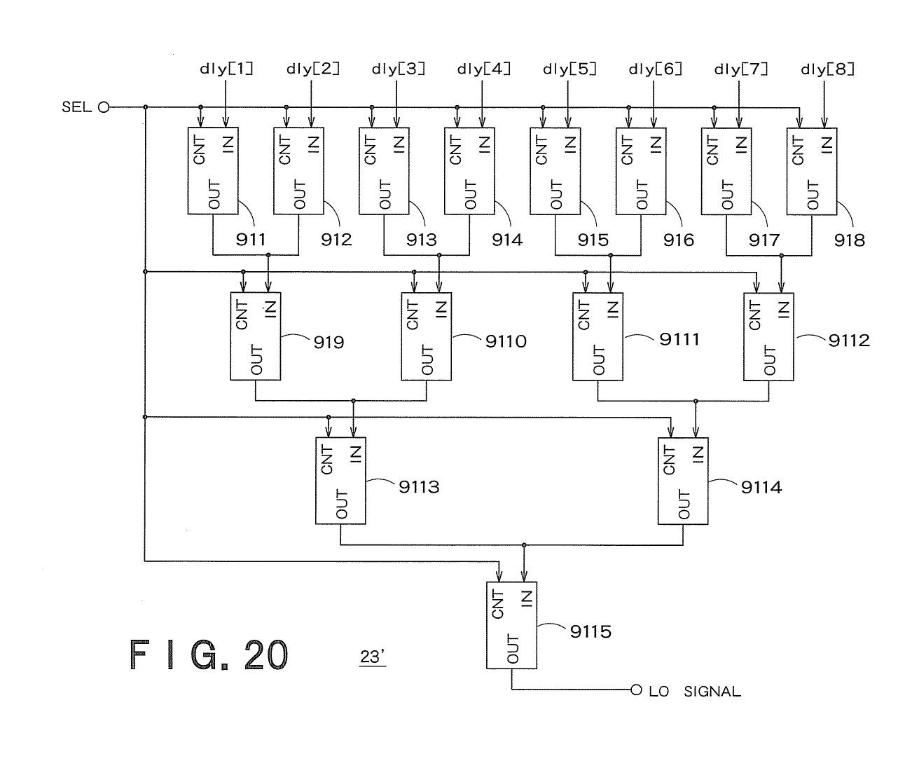

FIG. 20 is a schematic block diagram showing another example of the internal configuration of the MUX 23. In the example shown in FIG. 20, eight delay signals dly[1] to dly[8] are generated. A MUX 23′ has output buffers 911 to 9115.

The delay signals dly[1] to dly[8] are inputted to the output buffers (first output circuits) 911 to 918 through the input terminals IN respectively, and each of the output buffers determines whether or not to output the delay signal from the output terminal OUT depending on the control signal SEL. The input terminal IN of the output buffer (second output circuit) 919 is connected to the output terminals OUT of the output buffers 911 and 912 short-circuited to each other. The output buffers 9110 to 9112 are similarly arranged. Each of the output buffers (third output circuits) 9113 to 9115 combines the output signals from the output buffers 919 to 9114 depending on the control signal SEL to generate the LO signal. The other operations are similar to the sixth embodiment.

As stated above, in the sixth embodiment, the output terminals OUT of some output buffers are connected to the input terminal IN of the output buffer in the next stage instead of short-circuiting the output terminals OUT of all output buffers. Therefore, the number of output terminals of short-circuited output buffers is reduced, and thus the parasitic capacitance of the short-circuited node can be reduced. As a result, the edge of the signal of each terminal becomes steep, by which influence of element variation and noise can be reduced. Note that the MUX 23′ of FIG. 20 can be variously modified. For example, in FIG. 20, two output buffers are short-circuited, but four output buffers may be short-circuited, for example. In this case, the parasitic capacitance of the short-circuited node is increased, but the parasitic capacitance is smaller compared to the case of FIG. 19 and the circuit scale can be more reduced compared to the case of FIG. 20. Further, when the number of delay signals is four, it is unnecessary to arrange the output buffers 915 to 918, and 9111 to 9115 of FIG. 20. In this case, the output terminals of the output buffers 919 and 9110 short-circuited to each other can be regarded as third output circuits.

### Eighth Embodiment

In the sixth and seventh embodiments, the decoder circuit 33 sets one bit of the control signal SEL to be high. On the other hand, in an eighth embodiment to be explained below, one or more bits are set to be high.

The MUX 23 in the present embodiment is formed similarly to FIG. 19 in the sixth embodiment. Note that, as shown in FIG. 18, when the phase of the reference signal REF matches those of a plurality of delay signals, the decoder circuit 33 sets high for not one but all bits of the control signal SEL corresponding to the delay signals determined as phase matching. For example, when the phase of the reference signal REF matches those of five delay signals dly[2] to dly[6], the decoder circuit 33 sets the 2n d to 6th bits of the control signal SEL to be high and sets the other bits to be low.

By such a manner, the delay signals dly[2] to dly[6] are outputted from the output terminals OUT of the output buffer 812 to 816 respectively, and the MUX 23 combines these delay signals to output the LO signal. More specifically, the LO signal outputted from the MUX 23 has a value obtained by averaging the delay times of the delay signals dly[2] to dly[6] with respect to the original LO signal.

In the sixth embodiment, when a plurality of delay signals are determined to have a phase matching that of the reference signal REF, the MUX 23 selects only one of them to output the LO signal. Because the phase of the reference signal REF and that of the selected delay signal do not strictly match each other, and phase noise can be included in the selected delay signal.

On the other hand, in the present embodiment, by averaging the delay times of a plurality of delay signals determined as phase matching, phase noise of the LO signal to be outputted can be reduced. This is because, when “n” delay signals are determined to have phases matching that of the reference signal REF, the standard deviation of the mean delay time value becomes 1/√n based on a central limit theorem.

As stated above, in the eighth embodiment, when there are a plurality of delay signals having phases matching that of the reference signal REF, the MUX 23 combines these delay signals to output the LO signal. Therefore, phase noise of the LO signal can be further reduced.

### Ninth Embodiment

A ninth embodiment is a modification example of the eighth embodiment, in which the control signal SEL is inputted into the output buffers through a digital filter.

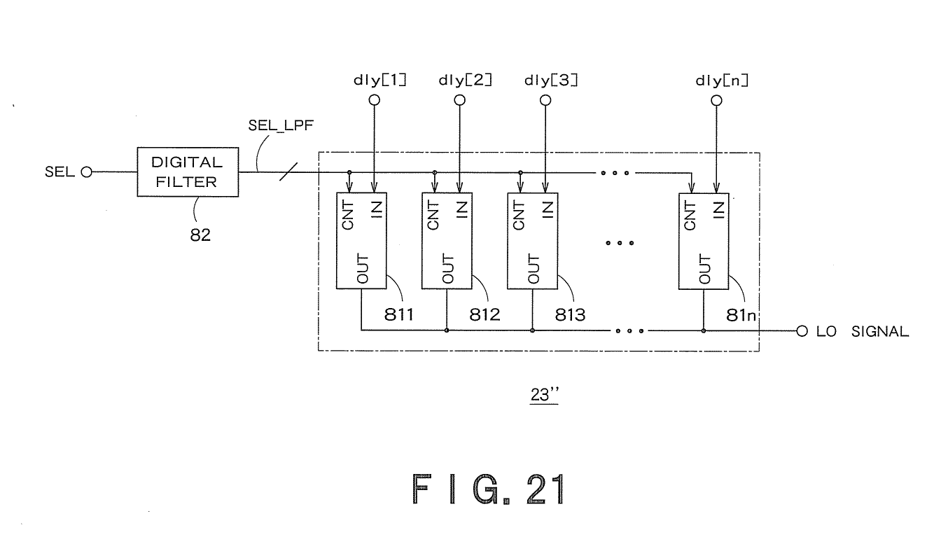

FIG. 21 is a schematic block diagram showing another example of the internal configuration of the MUX 23. In FIG. 21, the same components as those in FIG. 19 are given the same reference numerals, and differences will be mainly explained hereinafter. A MUX 23″ of FIG. 21 further has a digital filter 82. The control signal SEL is inputted to the digital filter 82, and k-th bit of its output signal SEL_LPF is inputted into the input terminal of the output buffer 81k.

The digital filter 82 is a counter circuit, for example, and once a certain bit of the control signal SEL is set to be high, the digital filter 82 continuously sets the corresponding bit of the output signal SEL_LPF to be high for a predetermined time. Accordingly, the MUX 23″ generates the LO signal by averaging the delay times of a plurality of delay signals each having a phase currently or previously matching that of the reference signal REF. Therefore, it is possible to remove high frequency components included in the phase error of the LO signal to be outputted.

The digital filter may be a low pass filter instead of the counter circuit, as long as it performs low-pass filter processing on the control signal SEL generated based on the determination results OUT[1] to OUT[n] from the phase matching detecting circuits 321 to 32n so that a smoothed control signal SEL_LPF is generated.

As stated above, in the ninth embodiment, the control signal SEL is inputted into the output buffers 811 to 81n through the digital filter 82. Therefore, it is possible to remove high frequency components included in the phase error of the LO signal.

Each circuit shown in FIGS. 7, 10 and so on, is merely an example, and various modifications can be conceivable. For example, at least a part of MOS transistors can be replaced by other semiconductor elements such as bipolar transistor, Bi-CMOS, etc. Further, it is also possible to form the circuit by reversing the conductivity type of the transistor while correspondingly reversing the positions of the power source terminal and the ground terminal. Also in this case, the fundamental operating principle is the same.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A semiconductor integrated circuit comprising:
a phase shifter configured to delay an input oscillation signal to generate a plurality of delay signals having phases different from each other;
a plurality of phase matching detecting circuits corresponding to the delay signals respectively, each of the phase matching detecting circuits being configured to determine whether a phase difference between a reference signal and corresponding one of the delay signals is within a predetermined range; and
an output module configured to generate an output oscillation signal based on at least one of the delay signals having the phase difference determined to be within the predetermined range.

2. The circuit of claim 1, wherein each of the phase matching detecting circuits comprises:
a phase difference detecting circuit configured to set a first signal to a first reference voltage corresponding to a power supply voltage or a second reference voltage corresponding to a ground voltage depending on the phase difference between the reference signal and the corresponding one of the delay signals when the phase difference is not within the predetermined range, and configured to set the first signal to a first voltage between the first reference voltage and the second reference voltage when the phase difference is within the predetermined range; and
a determination circuit configured to determine, based on the first signal, whether the phase difference between the reference signal and the corresponding one of the delay signals is within the predetermined range.

3. The circuit of claim 2, wherein the determination circuit comprises:
a first comparison circuit configured to compare the first signal with a second voltage which is higher than the first voltage and is lower than the first reference voltage;
a second comparison circuit configured to compare the first signal with a third voltage which is lower than the first voltage and is higher than the second reference voltage; and
a logic circuit configured to determine that the phase difference is within the predetermined range when comparison results of the first and second comparison circuits do not match each other, and configured to determine that the phase difference is not within the predetermined range when the comparison results match each other.

4. The circuit of claim 2, wherein the phase difference detecting circuit comprises:
a first transistor configured to pre-charge the first signal with the first reference voltage at a predetermined timing; and
second and third transistors connected in series,
wherein the reference signal is inputted to a control terminal of the second transistor,
the corresponding one of the delay signals is inputted to a control terminal of the third transistor, and
the first signal is outputted from the second transistor or the third transistor.

5. The circuit of claim 2, wherein the phase difference detecting circuit is configured to:
compare the corresponding one of the delay signals with an inversion signal thereof in synchronization with the reference signal;
set the first signal and a second signal to be the first reference voltage when the phase difference is within the predetermined range; and
set the first or the second signal to be the second reference voltage when the phase difference is not within the predetermined range, and
wherein the determination circuit comprises a logic circuit configured to determine that the phase difference is within the predetermined range when the first and the second signals are the first reference voltage, and configured to determine that the phase difference is not within the predetermined range when the first or the second signal is the second reference voltage in synchronization with a delay signal of the reference signal.

6. The circuit of claim 2, wherein the phase shifter has a plurality of delay elements connected in series, connection nodes of the delay elements outputting the delay signals, and
the number of the delay elements “n” satisfies a following equation (1):
Flo*ΔT<n (1)
where Flo represents a frequency of the input oscillation signal, and ΔT represents delay time of each of the delay elements.

7. The circuit of claim 1, wherein the phase shifter comprises:
a frequency dividing circuit configured to divide a frequency of the input oscillation signal to generate a plurality of frequency-divided signals; and
a plurality of impedance elements configured to generate the delay signals by dividing voltages of the frequency-divided signals.

8. The circuit of claim 7, wherein the divider circuit is configured to generate first to fourth frequency-divided signals having phases different from each other by “90” degrees, t
he impedance elements comprise first to fourth impedance elements connected in series between the k-th (“k” is an integer of “1” to “3”) frequency-divided signal and the (k+1)-th frequency-divided signal, and between the fourth frequency-divided signal and the first frequency-divided signal, and
a following equation (2) is satisfied
r1=√2*r2 (2)
where r1 is an impedance value of the first and fourth impedance elements, and r2 is an impedance value of the second and third impedance elements.

9. The circuit of claim 1, wherein the phase shifter comprises:
a first inverter circuit one of the delay signals is inputted to; and
a second inverter circuit another one of the delay signals is inputted to,
wherein outputs of the first and the second inverter circuits are short-circuited to generate one of the delay signals.

10. The circuit of claim 1, wherein the output module is configured to comprise a plurality of output circuits corresponding to the delay signals, each of the output circuits being configured to determine whether to output corresponding one of the delay signals from an output terminal based on a determination result of one of the phase matching detecting circuits corresponding to the corresponding one of the delay signals,
the output terminals of the output circuits are short-circuited to each other, and
the short-circuited output terminals are configured to generate the output oscillation signal by combining one or more delay signals each determined by the corresponding one of the phase matching detecting circuits to have the phase difference within the predetermined range.

11. The circuit of claim 1, wherein the output module comprises:
a plurality of output circuits corresponding to the delay signals, each of the first output circuits being configured to determine whether to output corresponding one of the delay signals from an output terminal based on a determination result of one of the phase matching detecting circuits corresponding to the corresponding one of the delay signals;
a plurality of second output circuits each configured to have an input terminal connected to the output terminal of one of the first output circuits or the output terminals of two or more of the first output circuits short-circuited to each other, and configured to determine whether to output a signal inputted to the input terminal from an output terminal based on a determination result of the phase matching detecting circuits; and
a third output circuit configured to generate the output oscillation signal by combining output signals from the second output circuits.

12. The circuit of claim 1, further comprising a filter configured to perform low-pass filter processing on determination results of the phase matching detecting circuits.

13. A radio communication device comprising at least one of a signal transmitter and a signal receiver,
wherein the signal transmitter is configured to comprise:
a first oscillation signal generating circuit configured to generate a first input oscillation signal;
a first phase adjustment circuit configured to generate a first output oscillation signal by reducing phase noise in the first input oscillation signal;
a modulation circuit configured to modulate an input signal inputted from an outside based on the first output oscillation signal; and
a transmitting module configured to transmit the modulated input signal to an antenna,
wherein the signal receiver is configured to comprise:
a second oscillation signal generating circuit configured to generate a second input oscillation signal;
a second phase adjustment circuit configured to generate a second output oscillation signal by reducing phase noise in the second input oscillation signal;
a demodulation circuit configured to demodulate a received signal received by the antenna based on the second output oscillation signal; and
an output circuit configured to output the demodulated received signal to the outside,
wherein each of the first and the second phase adjustment circuit is configured to comprise:
a phase shifter configured to delay the first or the second input oscillation signal to generate a plurality of delay signals having phases different from each other;
a plurality of phase matching detecting circuits corresponding to the delay signals respectively, each of the phase matching detecting circuits being configured to determine whether a phase difference between a reference signal and corresponding one of the delay signals is within a predetermined range; and
an output module configured to generate the first or the second output oscillation signal based on at least one of the delay signals having the phase difference determined to be within the predetermined range.

14. The device of claim 13, wherein each of the phase matching detecting circuits comprises:
a phase difference detecting circuit configured to set a first signal to a first reference voltage corresponding to a power supply voltage or a second reference voltage corresponding to a ground voltage depending on the phase difference between the reference signal and the corresponding one of the delay signals when the phase difference is not within the predetermined range, and configured to set the first signal to a first voltage between the first reference voltage and the second reference voltage when the phase difference is within the predetermined range; and
a determination circuit configured to determine, based on the first signal, whether the phase difference between the reference signal and the corresponding one of the delay signals is within the predetermined range.

15. The device of claim 14, wherein the determination circuit comprises:
a first comparison circuit configured to compare the first signal with a second voltage which is higher than the first voltage and is lower than the first reference voltage;
a second comparison circuit configured to compare the first signal with a third voltage which is lower than the first voltage and is higher than the second reference voltage; and
a logic circuit configured to determine that the phase difference is within the predetermined range when comparison results of the first and second comparison circuits do not match each other, and configured to determine that the phase difference is not within the predetermined range when the comparison results match each other.

16. The device of claim 14, wherein the phase difference detecting circuit comprises:
a first transistor configured to pre-charge the first signal with the first reference voltage at a predetermined timing; and
second and third transistors connected in series, wherein the reference signal is inputted to a control terminal of the second transistor,
the corresponding one of the delay signals is inputted to a control terminal of the third transistor, and
the first signal is outputted from the second transistor or the third transistor.

17. The device of claim 14, wherein the phase difference detecting circuit is configured to:
compare the corresponding one of the delay signals with an inversion signal thereof in synchronization with the reference signal;
set the first signal and a second signal to be the first reference voltage when the phase difference is within the predetermined range; and
set the first or the second signal to be the second reference voltage when the phase difference is not within the predetermined range, and
wherein the determination circuit comprises a logic circuit configured to determine that the phase difference is within the predetermined range when the first and the second signals are the first reference voltage, and configured to determine that the phase difference is not within the predetermined range when the first or the second signal is the second reference voltage in synchronization with a delay signal of the reference signal.

18. The device of claim 13, wherein the phase shifter has a plurality of delay elements connected in series, connection nodes of the delay elements outputting the delay signals, and the number of the delay elements “n” satisfies a following equation (1):
Flo*ΔT<n (1)
where Flo represents a frequency of the first or the second input oscillation signal, and ΔT represents delay time of each of the delay elements.

19. The device of claim 13, wherein the phase shifter comprises:
a frequency dividing circuit configured to divide a frequency of the first or the second input oscillation signal to generate a plurality of frequency-divided signals; and
a plurality of impedance elements configured to generate the delay signals by dividing voltages of the frequency-divided signals.

20. The device of claim 19, wherein the divider circuit is configured to generate first to fourth frequency-divided signals having phases different from each other by “90” degrees,
the impedance elements comprise first to fourth impedance elements connected in series between the k-th (“k” is an integer of “1” to “3”) frequency-divided signal and the (k+1)-th frequency-divided signal, and between the fourth frequency-divided signal and the first frequency-divided signal, and
a following equation (2) is satisfied
r1=√2*r2 (2)
where r1 is an impedance value of the first and fourth impedance elements, and r2 is an impedance value of the second and third impedance elements.
